(19) United States
(12) Patent Application Publication
(10) Pub. No.: US 2016/0095262 A1
(43) Pub. Date: Mar. 31, 2016

(54) ELECTRONIC DEVICE

(71) Applicant: HANGZHOU H3C TECHNOLOGIES CO., LTD., Zhejiang (CN)

(72) Inventors: Jianming DING, Beijing (CN); Huanyi WANG, Beijing (CN); Youxin BAI, Beijing (CN); Huanjun ZHANG, Beijing (CN); Yubin WANG, Beijing (CN); Minjie TONG, Beijing (CN); Libo ZHANG, Beijing (CN); Hongqin WANG, Beijing (CN); Guosong MA, Beijing (CN); Suxia ZHAO, Beijing (CN)

(21) Appl. No.: 14/892,140

(22) PCT Filed: May 22, 2014
(86) PCT No.: PCT/CN2014/078099

§ 371 Date: Nov. 18, 2015

(30) Foreign Application Priority Data
May 23, 2013 (CN) 201320291581.X
Aug. 7, 2013 (CN) 201320478767.6

(51) Int. Cl. H05K 7/20; H05K 7/18

(52) U.S. Cl. CPC H05K 7/20727; H05K 7/183

(57) ABSTRACT

An electronic device includes a group of first cards and a group of second cards, wherein the group of first cards and the group of second cards are arranged orthogonally. An air path extends between a front part and a rear part of a chassis and a fan is positioned on at least one side of the group of second cards. An opening is formed in a second card to connect an air inlet of the fan with the air path extending between the front part and the rear part of the chassis.

### BACKGROUND

Electronic device, such as a switch, router, server etc., may include a chassis. Inside the chassis, there may be a backplane, a power supply, and cards arranged in an orthogonal architecture in front of and behind the backplane. To facilitate heat dissipation, a fan may be provided inside the chassis of the electronic device. Accordingly, an air path for flow of air driven by the fan may be formed inside the chassis.

### BRIEF DESCRIPTION OF THE DRAWINGS

Features of the present disclosure are illustrated by way of example and not limited in the following figure(s), in which like numerals indicate like elements, in which:

FIG. 1a shows an example structure of an electronic device according to the present disclosure;

FIG. 1b shows another example structure of an electronic device according to the present disclosure;

FIG. 2 shows an example of openings processed on a plurality of second cards of the electronic device according to the present disclosure;

FIG. 3 shows an example structure of an electronic device in which heats are dissipated by a centrifugal fan according to the present disclosure;

FIG. 4 shows an example structure of an electronic device in which heats are dissipated by an axial fan according to the present disclosure;

FIG. 5 shows an example of another structure according to the present disclosure;

FIG. 6 shows another example structure of an electronic device in which heats are dissipated by an axial fan according to the present disclosure;

FIG. 7 shows an example of another structure according to the present disclosure;

FIG. 8 shows another example structure of an electronic device in which heats are dissipated by an axial fan according to the present disclosure;

FIG. 9 shows an example of another structure according to the present disclosure;

FIG. 10 shows an example assemblage structure of an electronic device according to the present disclosure;

FIG. 11 shows an example of an air path in the electronic device according to the present disclosure;

FIG. 12a shows an example structure of a backplane of the electronic device according to the present disclosure;

FIG. 12b shows another example structure of a backplane of the electronic device according to the present disclosure; and

FIG. 12c shows still another example structure of a backplane of the electronic device according to the present disclosure.

### DETAILED DESCRIPTION

Hereinafter, the present disclosure is described in further detail with reference to the accompanying drawings and examples.

For simplicity and illustrative purposes, the present disclosure is described by referring to examples. In the following description, numerous specific details are set forth in order to provide a thorough understanding of the present disclosure. It will be readily apparent however, that the present disclosure may be practiced without limitation to these specific details. In other instances, some structures have not been described in detail so as not to unnecessarily obscure the present disclosure. As used herein, the term “includes” means includes but not limited to, the term “including” means including but not limited to. The term “based on” means based at least in part on. In addition, the terms “a” and “an” are intended to denote at least one of a particular element.

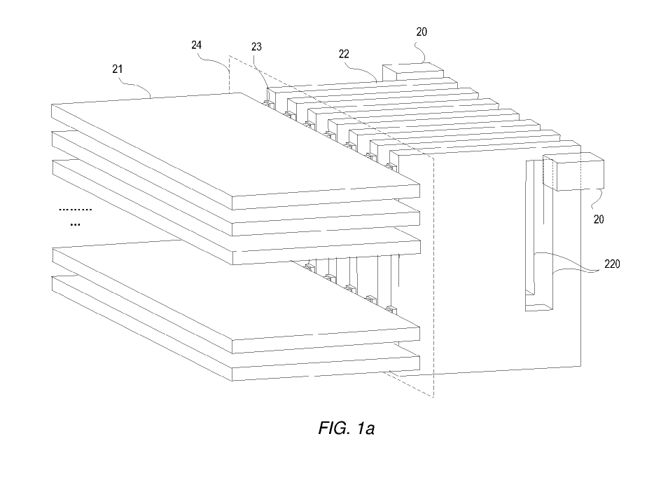

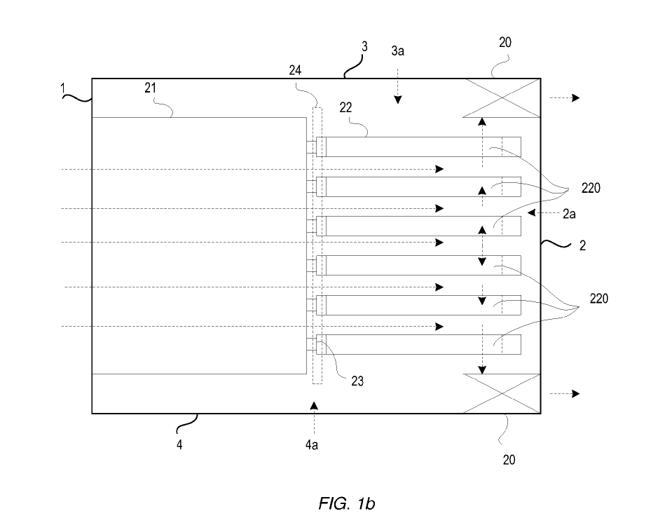

FIGS. 1a and 1b show example structures of an electronic device according to the present disclosure. As shown in FIGS. 1a and 1b, the electronic device includes: a chassis (shown in FIG. 1b), a group of first cards 21 arranged in the front part of the chassis and a group of second cards 22 arranged in the rear part of the chassis. The group of first cards 21 is arranged orthogonally with respect to the group of second cards 22. Arranged “orthogonally” means that the orientation of the first group of card and the orientation of the second group of cards are substantially perpendicular to each other. The orientation of a group of cards may be defined by a plane each of the cards in the group is substantially parallel to. A line between the front and rear of the cards along the plane may be referred to as an “arranging direction” of the cards. An air path extending between the front part and the rear part of the chassis is formed (arrows in FIG. 1b denote airflow paths in the air path).

It should be noted that, in this example, the plurality of first cards 21 are arranged in a vertical direction and the plurality of second cards 22 are arranged in a horizontal direction. The vertical direction meaning that the plane of the cards extends in direction from top to bottom of the chassis. The horizontal direction meaning that the plane of the cards extends in the direction from front to back or side to side of the chassis. The vertical direction and the horizontal direction mentioned in this example are determined by a placed direction of the chassis of the electronic device. If the chassis is turned over, the vertical direction and the horizontal direction may exchange or have offsets with a same angle.

The orthogonal connection of the group of first cards 21 and the group of second cards 22 may be implemented by a matrix of orthogonal connectors 23. An orthogonal connector is a connector which connects the cards in an orthogonal manner. There may be a space between the orthogonal connectors 23 in the matrix to allow flow of air along the air path. If the electronic device has a backplane 24 (shown by dotted lines in FIGS. 1a and 1b), then the group of first cards 21 and the group of second cards 22 may be orthogonally connected via orthogonal connectors 23 on the backplane 24, and the backplane may include one or more openings (not shown) to allow flow of the air along the air path and through the backplane.

In addition, fans 20 may be positioned on both sides of the group of second cards 22 of the electronic device. That is the fans may be positioned between a side wall of the chassis and the second group of cards, rather than behind the second group of cards between the ends of the second group of cards and the back wall of the chassis. Openings 220 may be provided in some or all of the second cards 22 to connect an air inlet of the fan 20 with the air path extending between the front part and the rear part of the chassis.

It should be noted that, in this example, one fan 20 is provided on each side of the group of second cards 22. In another example, the fan 20 may be provided on only one side of the group of second cards 22. Whether the fan 20 is provided on one or two sides, there may be more than one fan 20 on each side.

Thus, air may be driven by the fan 20 on the side of the group of second card 22, so that air flows from the front part of the chassis to the group of first cards 21 and the group of second cards 22, and then turns to two sides of the group of second cards 22 at the openings 220 in the group of second cards 22, and finally flows out from the rear part of the chassis through the fan 20 on the side of the group of second cards 22. Thus, heat dissipation is realized.

In FIG. 1b an example chassis is depicted schematically. The chassis may include a front wall 1, a back wall 2 opposite the front panel and two opposing side walls 3 and 4. The walls may be removable and/or may include a door to allow access to the interior etc. Areas to the side of the group of second cards 22 are indicated generally by arrows 3a and 4a, while an area to the back of the group of second cards 22 is indicated generally by arrow 2a.

In view of the above, in the example, the fan 20 is provided on the side of the group of the second cards 22 and is connected with the air path from the front to rear of the chassis via the openings 220 processed on the second cards 22. Thus, heat may be dissipated by the fan. In addition, positioning the fan 20 on the side of the group of the second cards 22, rather than at the rear of the group of second cards, makes it possible to perform a plug operation at the rear side of the group of the second cards 22. Thus there may be easy access to the second group of cards so that cards in the second group may be plugged or unplugged from the orthogonal connectors or backplane without first moving a fan. This arrangement may allow for more convenient plug and maintenance of the group of the second cards 22.

Accordingly, since the fan 20 does not affect the plug and replacement of the group of the second cards 22, if there is more than one fan 20 on each side, the plurality of fans 20 need not be integrated into a fan box to facilitate assembling and disassembling operations of the fans 20. Instead, each fan may form an independent fan box. Thus, maintenance cost of the fans may be reduced.

Besides making way for the plug operation at the rear side of the group of the second cards 22, positioning the fan 20 on the side of the group of the second cards 22 may allow for electrical connection space between the group of second cards and the back wall of the chassis. Thus, the group of the second cards may be electrically connected with the back wall of the chassis. In this case, a port connected with a card 22 of the group of the second cards may be configured on the back wall of the chassis.

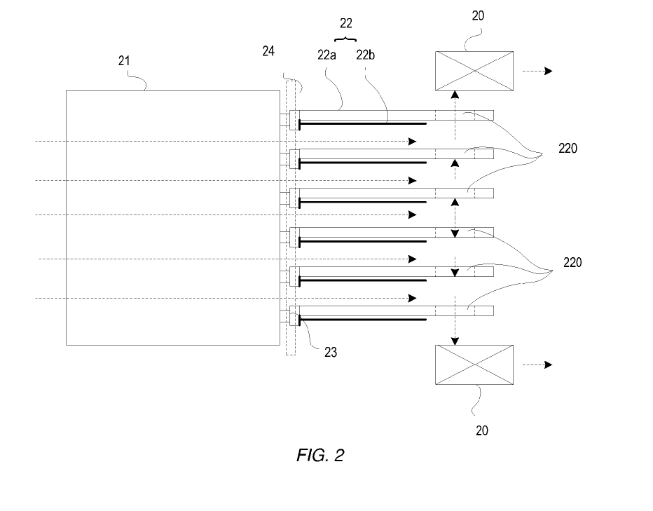

FIG. 2 shows an example of openings in a plurality of second cards of the electronic device. As shown in FIG. 2, in order to facilitate the plug and maintenance operation, each second card 22 may include a tray 22a for implementing the plug and push/pull operation, and a printed circuit board (PCB) 22b which is provided on or attached to the tray 22a. The tray may be easily graspable by a user to facilitate the plug in or unplugging of the card. The PCB 22b may include logic circuitry to implement the basic functions of the second card 22. The opening 220 is included on the rear part of the tray 22a. The PCB 22b is indented towards the front part of the tray 22a, i.e., the PCB 22b is shorter than the tray 22a and thus does not overlap with a rear part of the tray 22a. The opening 220 is provided on the rear part of the tray 22a. Thus, the PCB 22b does not get in the way of the opening or the air flow.

In another example, the PCB 22b may be not indented towards the front part of the tray 22a. Instead, the opening 220 may extend through both the tray 22a and the PCB 22b. Thus, the size of the PCB 22b may be as large as possible.

In yet another example, the second card 22 may not include the tray but merely a PCB. Accordingly, an opening 220 is simply provided on the PCB.

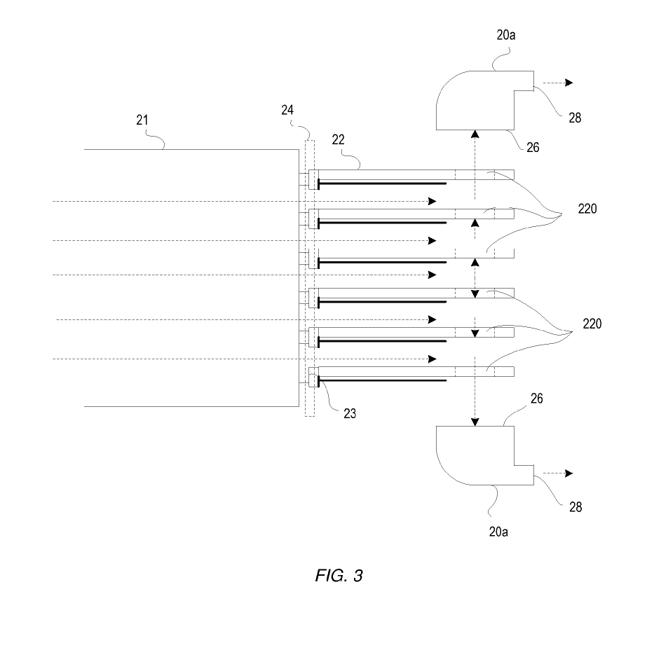

FIG. 3 shows an example structure of an electronic device in which heat is dissipated via a centrifugal fan. The plurality of second cards has openings as described above for FIG. 2. If centrifugal fans 20a are utilized, an air inlet 26 of the centrifugal fan 20a faces the openings 220 of the plurality of second cards, and an air outlet 28 of the centrifugal fan 20a faces the back wall of the chassis.

Thus, since the air inlet 26 of the centrifugal fan 20a faces the openings 220 of the plurality of second cards 22, air may flow under the drive of the centrifugal fan 20a from the front part of the chassis to the plurality of first cards 21 and the plurality of second cards 22, and turn to two sides of the plurality of the second cards 22 via the openings 220 of the second cards, flow into the centrifugal fan 20a, and flow out via the air outlet 28 facing the back wall of the chassis after passing through the centrifugal fan 20a.

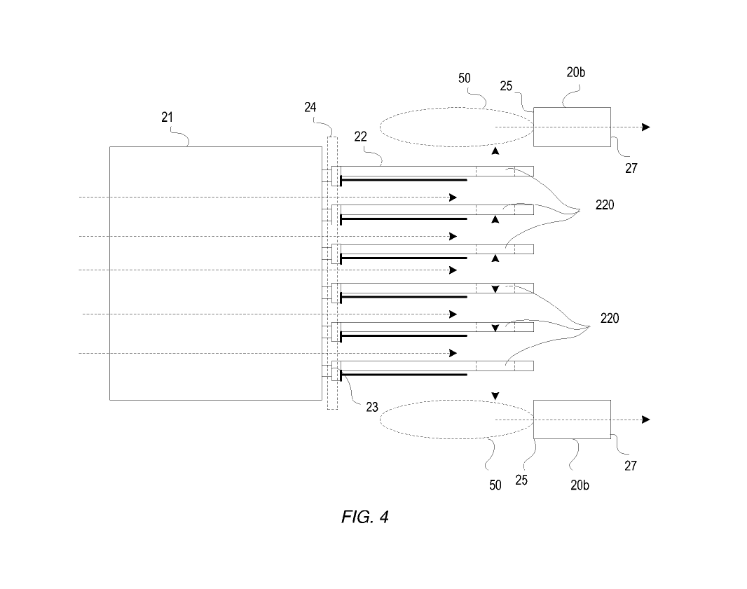

FIG. 4 shows an example of an electronic device in which heat is dissipated via an axial fan. The plurality of second cards has openings as described above for FIG. 2. If axial fans are utilized, an air inlet 25 of the axial fan 20b is close to the side near the back wall of the chassis of the opening 220, faces the front part of the chassis, and an air outlet 27 of the axial fan 20b faces the back wall of the chassis.

Thus, the axial fan 20b on each side is able to form a negative pressure area 50 on this side of the second cards 22. Therefore, due to the existence of the negative pressure area 50, the air may flow from the front part of the chassis to the first cards 21 and the second cards 22, turn to two sides of the second cards via the openings 220 of the second cards 22, enter into the negative pressure area 50 and is absorbed into air inlet of the axial fan 20b, and then flow out from the air outlet 27 of the axial fan 20b.

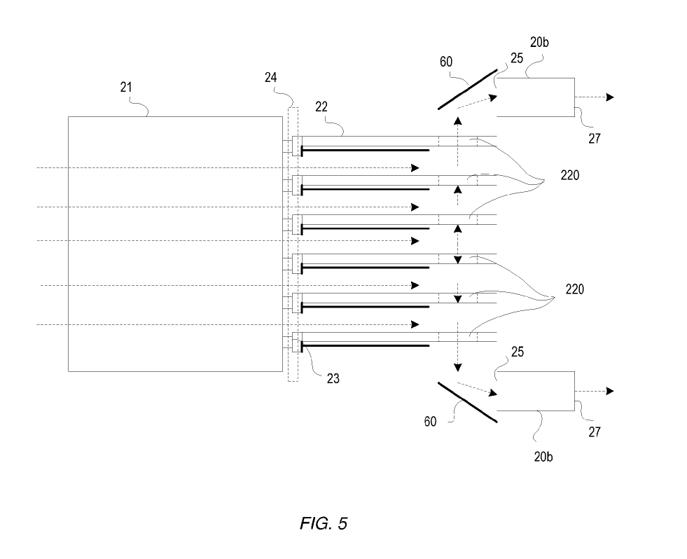

FIG. 5 shows an example of another structure according to the present disclosure. As shown in FIG. 5, a deflector 60 may be arranged in front of the air inlet 25 of the axial fan 20b to make the air flow from the openings 220 to the air inlet. Thus, the air flows out via the axial fan 20b under the deflecting of the deflector 60 after turns to two sides of the second cards 22 from the openings 220.

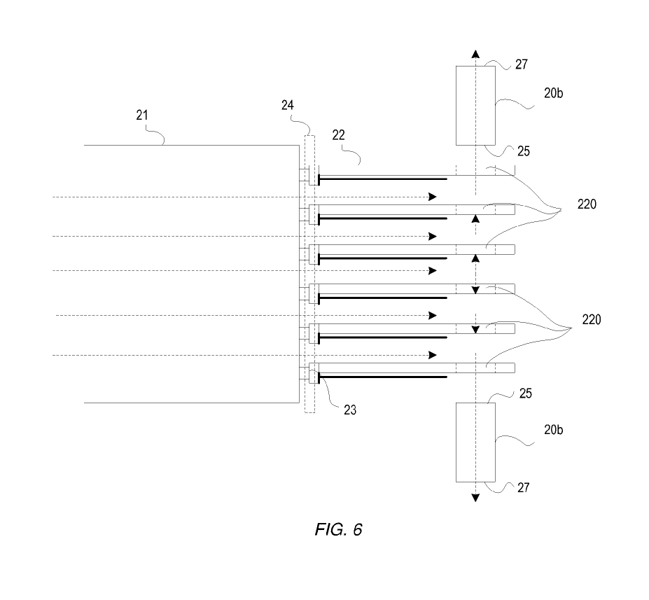

FIG. 6 shows an example of an electronic device in which heat is dissipated via an axial fan. The second cards 22 have openings described above for FIG. 2. The air inlet 25 of the axial fan 20b faces the openings 220 and the air outlet 27 of the axial fan 20b faces one side wall of the chassis (not shown).

The axial fan 20b on each side absorbs via the openings 220 the air from the second cards 22 to outside of the second cards 22, and vents the air from the side wall of the chassis (an air outlet may be configured on the side wall).

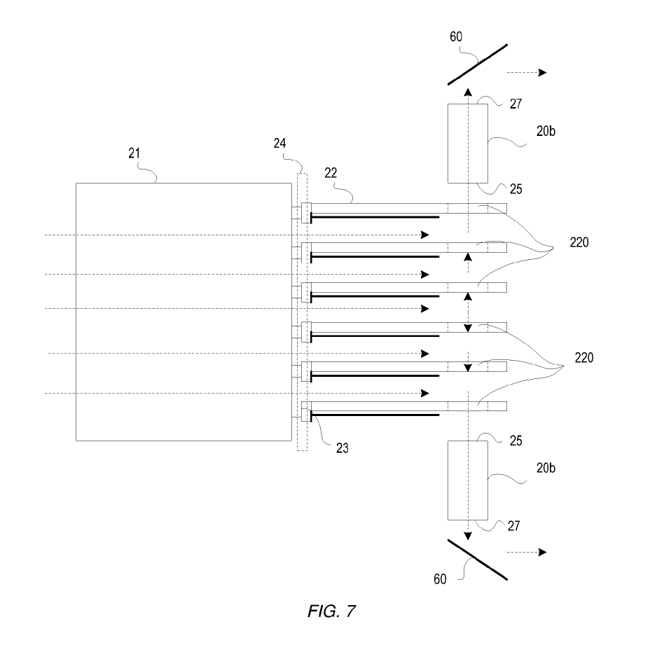

FIG. 7 shows an example of another structure according to the present disclosure. As shown in FIG. 7, a deflector 80 may be arranged in front of the air outlet 27 of the axial fan 20b to deflect the air to the back wall of the chassis, so as to vent the air from the back wall of the chassis.

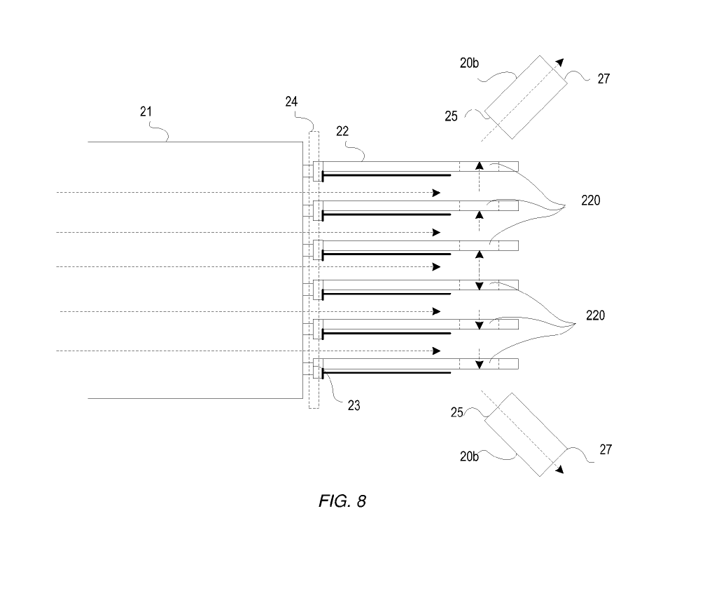

FIG. 8 shows an example of an electronic device in which heat is dissipated via an axial fan. The second cards have openings described above for FIG. 2. If axial fans 20b are utilized, there may be an angle between the axial fan 20b and an axis along which the second openings 22 are arranged. In addition, an air inlet 25 of the axial fan 20b is close to the openings 220 of the second openings 22, an air outlet 27 of the axial fan 20b is close to the side wall and the back wall of the chassis.

Thus, in this example the axial fan 20b, which is positioned at angle to the cards, performs approximately the deflecting function of the deflector 60 as shown in FIG. 5. It vents the air via the side wall of the chassis, or deflects the air to the back wall of the chassis utilizing the side wall and then vents the air via the back wall of the chassis.

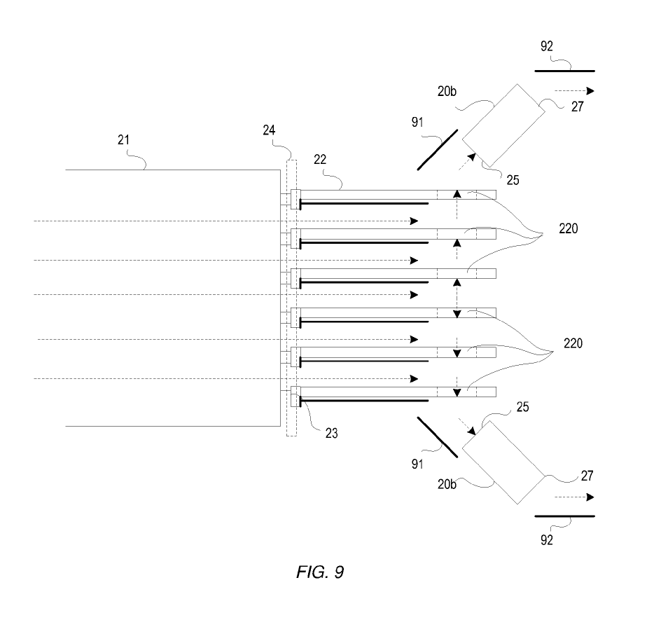

FIG. 9 shows an example of an extended structure based on FIG. 8. As shown in FIG. 9, a deflector 91 may be placed in front of the air inlet 25 of the axial fan 20b to deflect the air from the openings 220 to the air inlet 25. A deflector 92 may be placed in front of the air outlet 27 of the axial fan 20b to deflect the air from the air outlet 27 to the back wall of the chassis. Thus, deflection from the openings 220 to the axial fan 20b and the deflection from the axial fan 20b to the back wall of the chassis may join better and the air flows may be directed better.

The above examples describe the air path in the chassis and the deflection of the air path in the front and rear direction from the second openings to the fan 20 utilizing the openings 220. Hereinafter, examples of the structure of the electronic device, including the backplane and the power supply, which may support the above described air paths are described.

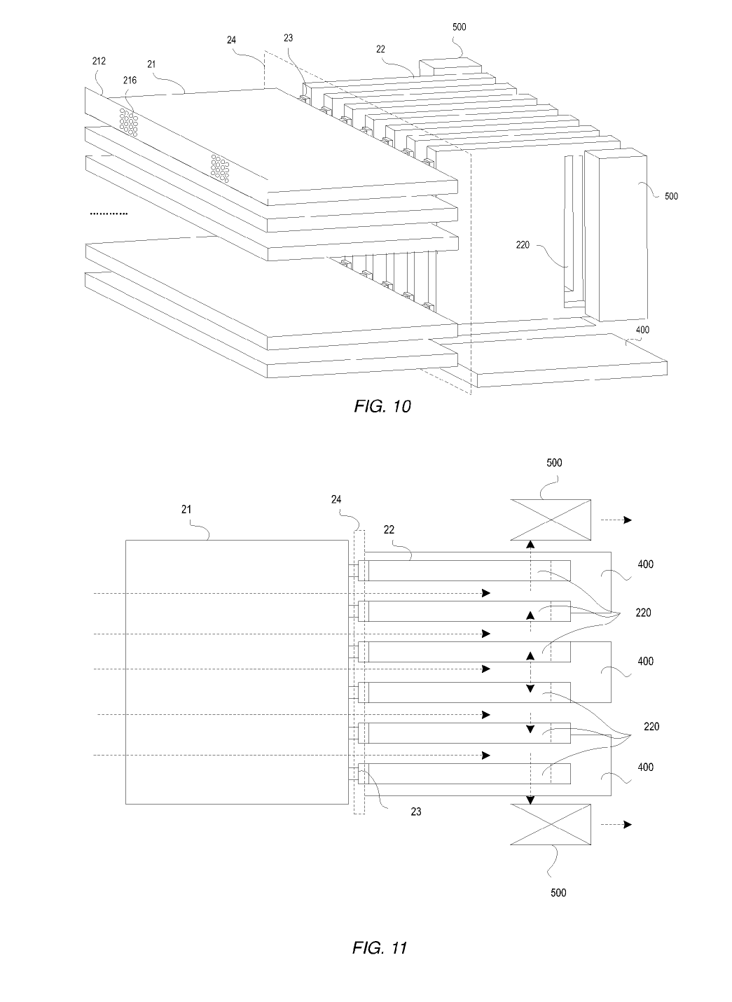

As shown in FIG. 10, an electronic device in this example includes a chassis (not shown), a backplane 24 inside the chassis, a group of first openings 21 arranged in the front part of the chassis and a group of second cards 22 arranged in the rear part of the chassis, a power supply 400 and a fan box 500 in which a plurality of fans 20 are placed. The group of first cards 21 is orthogonally connected with the group of second cards 22.

If the electronic device is a network device such as a switch or a router, the group of first cards 21 may include a service card and/or a main control card, the group of second cards 22 may include a switch network card. If the electronic device is a device implementing other functions, the group of first cards 21 and the group of second cards 22 may be cards with other functions. In addition, in an example, a plurality of independent fans may be provided instead of the fan box 500.

As shown in FIG. 10,
the group of first cards 21 is plugged in the front side the backplane 24. The group of second cards 22 is plugged in the rear side of the backplane 24. The group of first cards 21 is orthogonal with the group of second cards 22 to form the orthogonal architecture inside the chassis;
the power supply 400 is plugged in the rear side of the backplane 24 and is below the group of second cards 22, so as to not to interfere with the orthogonal architecture formed by the group of first cards 21 and the group of the second cards 22.

In this example, a plurality of power supplies 400 are arranged in a row below the group of second cards 22. The number of the power supplies and the number of rows may vary depending on the power requirements.

Thus, space in front of the backplane 24 may be completely utilized to arrange the group of first cards 21. Behind the backplane 24, the upper space and the middle space which account for majority of the space behind the backplane 24 are utilized to arrange the group of second cards 22. The lower space which accounts for minority of the space behind the backplane 24 is utilized to place the power supply 400. Thus, a compact orthogonal architecture is formed inside the chassis.

Referring to FIG. 10 and FIG. 11, a fan box 500 is configured on at least one side of the arranging direction of the group of second cards 22. Each of the second cards is processed with an opening 220. Openings are included in the backplane 24 at positions corresponding to the second cards, so as to form the air path which extends from the front end of the backplane 24, through the backplane 24 to the rear end of the backplane 24 and is deflected by the openings 220 of the second cards 22 to the fan box 500 (arrows in FIG. 11 denote the direction of the air flow in the air path).

Accordingly, as to the compact orthogonal architecture, by positioning the fan box 500 on at least one side of the second cards 22, including openings 220 on the second cards 22 and including openings on the upper and middle parts of the backplane 24 corresponding to the second cards 22, an air path is formed which begins from the front end of the backplane 24, goes through to the rear end of the backplane 24, and turns to at least one side where the fan box 500 is located via the openings 220 of the second cards 22. The compact orthogonal architecture is realized. In this way, heat may be dissipated via the air path extending from the front to rear of the chassis.

In this example, the second cards 22, the openings 220, the relative positions of the second cards 22, the openings 220 and the fan box 500, and the type of the fans in the fan box 500 may be modified according to the air path and configurations described in the above examples. If a deflector is used, the deflector may be provided as described in the above examples.

At least one first card 21 may have a front panel 212. The front panel 212 of the first card 21 may include at least one physical port. Since the space in front of the backplane 24 is utilized to arrange the first cards 21 with the physical ports, a port density on a front wall of the chassis may be increased.

In addition, openings 216 may be formed in the front panel 212 to act as an air inlet. Thus, air outside the chassis may flow into the air path as shown in FIG. 11. The openings shown in FIG. 11 are just an example and they may have a different shape or different number.

The group of first cards 21 may be plugged in a front side of the backplane 24 via sockets on the front side. The group of second cards 22 may be plugged in a rear side of the backplane 24 via sockets on the rear side. The first cards 21 and the second cards 22 may be connected via a plurality of orthogonal connectors to realize the orthogonal connection. Power supply 400 may be plugged in the rear side of the backplane 24 via sockets on the rear side.

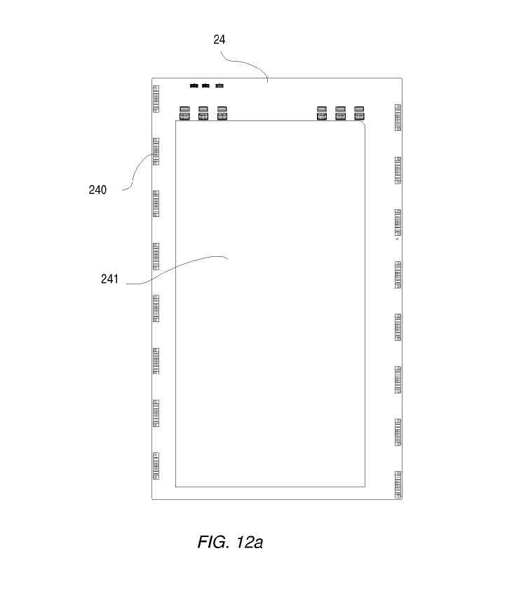

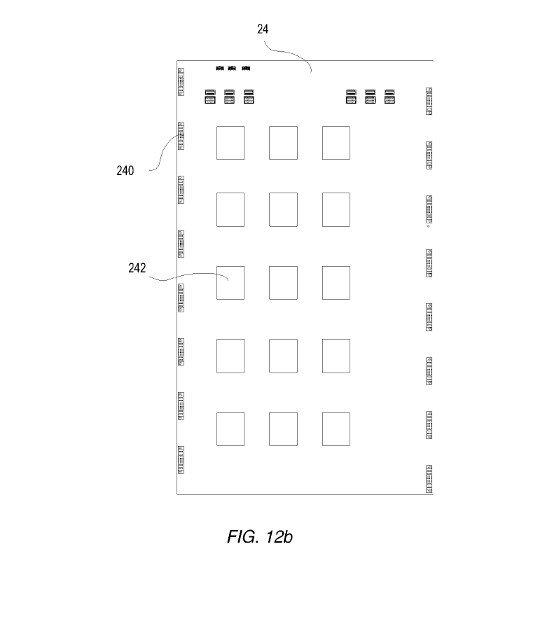

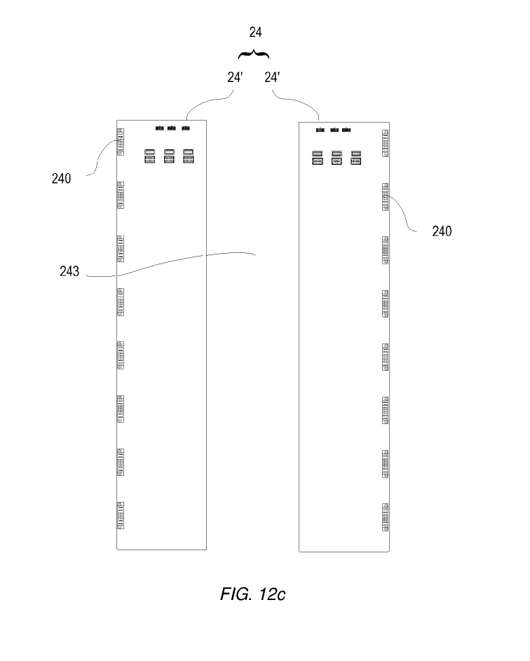

Referring to FIG. 12a which shows a rearview of the backplane 24, the opening in the backplane 24 may be a hollow area 241. The orthogonal connectors (not shown in FIG. 12a) may be configured in the hollow area 241. Sockets 240 used for plugging the second cards and the power supply 400 may be configured on outer parts of the backplane surrounding the hollow area 241. Similarly, on the front side of the backplane 24, the sockets used for plugging the first cards 21 may also be configured on outer parts of the backplane. Thus, the hollow area 214 is able to provide enough spaces for placing the orthogonal connectors. Air may flow through the spaces between the orthogonal connectors. Also, plugging of the first cards, the second cards and the power supply 400 is not affected by the hollow area.

Referring to FIG. 12b which shows a rearview of the backplane 24 according to another example, a plurality of openings may be included in the backplane 24. In this example, each orthogonal connector (not shown in FIG. 12b) may be located in one opening 242. The sockets 240 used for plugging the second cards and the power supply 400 may be provided on outer parts of the backplane, i.e. on edges surrounding the plurality of openings 242. Similarly, the sockets on the front side of the backplane 24 for plugging the first cards 21 may also be configured on outer parts of the backplane. Thus, the openings 242 are able to provide enough spaces for placing the orthogonal connectors. Air may flow through the spaces between the orthogonal connectors and the openings 242. Also, plugging of the first cards, the second cards and the power supply 400 is not affected by the openings.

Referring to FIG. 12c (which shows a rearview of the backplane 24), the backplane 24 may include two boards 24′. There is a gap 243 between the two boards 24′ to form the openings of the backplane 24. At this time, the orthogonal connectors (not shown in FIG. 12c) are located in the gap 243 between the two boards 24′. The sockets 240 used for plugging the second cards 22 and the power supply 400 may be configured on the two boards 24′ respectively. Similarly, the sockets on the front side of the backplane 24 used for plugging the first cards may also be configured on the two boards 24′ respectively. Thus, the gap 243 between the two boards 24′ is able to provide enough spaces for placing the orthogonal connectors. Air may flow through the spaces between the orthogonal connectors. Also, plugging of the first cards, the second cards and the power supply 400 is not affected

In addition, if electrical connection is required between the two boards 24′, lines may be placed between the two boards 24′. In an example, the backplane 24 may contain more than two boards which form the backplane 24 via various manners.

While in the above description a chassis is only illustrated in FIG. 1b, a similar chassis may be provided in the other examples.

What has been described and illustrated herein is an example of the disclosure along with some of its variations. The terms, descriptions and figures used herein are set forth by way of illustration. Many variations are possible within the spirit and scope of the disclosure, which is intended to be defined by the following claims and their equivalents.

What is claimed is:

1. An electronic device, comprising:
a group of first cards and a group of second cards, wherein the group of first cards and the group of second cards are arranged orthogonally to form an air path extending between a front part and a rear part of a chassis;
a fan configured on at least one side of the group of second cards; and
a card of the group of second cards includes an opening to connect an air inlet of the fan with the air path extending between the front part and the rear part of the chassis.

2. The electronic device of claim 1, further comprising a port on a back wall of the chassis, the port is connected with one of the second cards.

3. The electronic device of claim 1, wherein the fan is a centrifugal fan including an air inlet and an air outlet, the air inlet of the fan faces openings of the group of second cards and the air outlet of the fan faces a back wall of the chassis.

4. The electronic device of claim 1, wherein the fan is an axial fan, an air inlet of the axial fan is positioned beside the openings and faces a front wall of the chassis, and an air outlet of the axial fan faces a back wall of the chassis.

5. The electronic device of claim 4, further comprising a deflector positioned in front of the air inlet of the axial fan, to deflect air from the openings to the air inlet of the axial fan.

6. The electronic device of claim 1, wherein the fan is an axial fan, an air inlet of the axial fan faces openings of the group of second cards, and an air outlet of the axial fan faces a back wall of the axial fan.

7. The electronic device of claim 6, further comprising a deflector arranged in front of the air inlet of the axial fan, to deflect air to the back wall of the chassis.

8. The electronic device of claim 1, wherein the fan is an axial fan, there is an angle between the axial fan and an arranging direction of the group of second cards; an air inlet of the axial fan is beside openings of the group of second cards, and an air outlet of the axial fan faces a side wall and a back wall of the chassis.

9. The electronic device of claim 8, further comprising a deflector arranged in front of the air inlet of the axial fan, to deflect air from the openings to the air inlet; and
another deflector arranged in front of the air outlet of the axial fan to deflect the air to the back wall of the chassis.

10. The electronic device of claim 1, wherein a second card comprises a tray and a printed circuit board (PCB) on the tray;
and the opening extends through both a rear end of the tray and a rear end of the PCB.

11. The electronic device of claim 1, wherein the PCB is shorter than the tray, and an opening is formed on the rear part of the tray, wherein the rear part of the tray does not overlap with the PCB.

12. The electronic device of claim 1, further comprising: a backplane and a power supply inside the chassis;
each first card is plugged in a front side of the backplane via a socket, and each second card is plugged in a rear side of the backplane via a socket, the first card and the second card are connected orthogonally via an orthogonal connector;
the power supply is plugged in the rear side of the backplane via a socket and is below the group of second cards.

13. The electronic device of claim 12, wherein
the backplane includes an opening at a position corresponding to the second cards, the opening is a hollow area, and the orthogonal connectors are configured in the hollow area; or
the backplane includes a plurality of openings and each orthogonal connector is configured in one of said plurality of openings.

14. The electronic device of claim 12 wherein the backplane comprises two boards, there is a gap between the two boards to form an opening of the backplane, and all orthogonal connectors are configured in the gap between the two boards.

15. The electronic device of claim 1, wherein at least one first card comprises a front panel; an opening is processed in the front panel.
